(19) United States
(12) Patent Application Publication
(10) Pub. No.: US 2023/0123385 A1
(43) Pub. Date: Apr. 20, 2023

(54) POWER USAGE IN AN ELECTRICITY DISTRIBUTION APPARATUS FOR A PLURALITY OF ELECTRICAL LOADS

(71) Applicant: Eaton Intelligent Power Limited, Dublin 4 (IE)

(72) Inventors: Niall CAHILL, Dublin 15 (IE); Keith NOLAN, Mullingar (IE)

(21) Appl. No.: 17/906,015

(22) PCT Filed: Mar. 10, 2020
(86) PCT No.: PCT/EP2020/056335

§ 371 Date: Sep. 9, 2022

(51) Int. Cl. G01R 19/25; G01R 27/16

(52) U.S. Cl. CPC G01R 19/2513; G01R 27/16

(57) ABSTRACT

A method of estimating power usage in an electricity distribution apparatus for a plurality of electrical loads, the electricity distribution apparatus comprising an electrical circuit including a plurality of branch circuits arranged in parallel, each branch circuit being coupled to one or more of the plurality of electrical loads, the electrical distribution apparatus being configured to distribute electrical power, received via a supply line from a supply of electrical power, across the electrical circuit, the method comprising: measuring voltage across at least one of the plurality of branch circuits; measuring current in a monitored branch circuit of the plurality of branch circuits; and detecting a first type of load change event if there is a change in the measured current and a corresponding change in the measured voltage, wherein the change in the measured current and the corresponding change in the measured voltage correspond to a change of load.

### TECHNICAL FIELD

The present disclosure relates generally to a method for determining power usage of electrical appliances in a building using an electricity distribution apparatus of the building. Aspects of the disclosure relate to a method and to a control system of an electricity distribution apparatus.

### BACKGROUND

Typically a building includes an electricity distribution apparatus, such as a distribution panel board, configured to distribute a supply of electrical power to the various electrical circuits and appliances of the building. The electricity distribution apparatus usually receives electrical power from a local transformer of a power distribution network that connects to the electricity distribution apparatus via a service entrance. In this manner, the service entrance forms a supply line between the power distribution network and the electricity distribution apparatus.

The electricity distribution apparatus includes, or is connected to, a plurality of subsidiary circuits, known as branch circuits, arranged in parallel to provide electrical connections to the electrical appliances of the building. Each branch circuit apparatus is electrically connected to one or more of the electrical appliances and the electricity distribution apparatus comprises a protective fuse, or circuit breaker, for each branch circuit within a common enclosure.

Operating one of the electrical appliances creates a demand for electrical power known as an electrical load. The electricity distribution apparatus is configured to satisfy the various demands in the building by distributing the supply of electrical power, between the branch circuits, according to the respective electrical load in each branch circuit. In this manner, a suitable supply of electricity can be provided to power each of the electrical appliances of the building.

An electricity distribution apparatus is known that includes a plurality of current sensors and voltage sensors for the purposes of determining the power usage of the electrical appliances. With such an electricity distribution apparatus it is known to estimate the total power usage of the electrical appliances in the building by aggregating branch circuit power measurements together.

### SUMMARY OF THE DISCLOSURE

According to an aspect of the present disclosure there is provided a method of estimating power usage in an electricity distribution apparatus for a plurality of electrical loads, the electricity distribution apparatus comprising an electrical circuit including a plurality of branch circuits arranged in parallel, each branch circuit being coupled to one or more of the plurality of electrical loads, the electrical distribution apparatus being configured to distribute electrical power, received via a supply line from a supply of electrical power, across the electrical circuit, the method comprising: measuring a voltage across at least one of the plurality of branch circuits; and estimating a total amount of power usage in the electrical circuit in dependence on: the voltage of the supply of electrical power; the measured voltage; and an estimation of the line impedance in the supply line.

According to another aspect of the present disclosure there is provided a method of estimating power usage in an electricity distribution apparatus for a plurality of electrical loads (in a building). The electricity distribution apparatus comprises an electrical circuit including a plurality of branch circuits arranged in parallel. Each branch circuit is coupled to one or more of the plurality of electrical loads. The electrical distribution apparatus is configured to distribute electrical power, received via a supply line from a supply of electrical power, across the electrical circuit. The method comprises: measuring voltage across at least one of the plurality of branch circuits; measuring current in a monitored branch circuit of the plurality of branch circuits; and detecting a first type of load change event if there is a change in the measured current and a corresponding change in the measured voltage, wherein the change in the measured current and the corresponding change in the measured voltage correspond to a change of load on the electrical circuit provided by the one or more electrical loads in the monitored branch circuit; estimating line impedance in the supply line in dependence on detecting a load change event of the first type, wherein the estimation of the line impedance is based on the change in the measured current and the change in the measured voltage corresponding to the detected load change event of the first type; and estimating a total power usage of the electrical circuit based on: a voltage of the supply of electrical power; the measured voltage; and the estimation of the line impedance.

In this manner, the total power usage of the electrical circuit can be determined without measuring the current in each branch circuit. Advantageously, the need for current sensors in each branch circuit is therefore alleviated, which may reduce hardware complexity and costs.

The supply of electrical power, received via the supply line, may be an alternating supply of electrical power, having an amplitude and a frequency. Accordingly, the measured current may form an alternating current waveform, having peaks and troughs. Similarly, the measured voltage may form an alternating voltage waveform, having respective peaks and troughs.

The estimation of the line impedance may be an estimation of the effective resistance (i.e. impedance) of the supply line to alternating current, which may arise from the combined effects of ohmic resistance and reactance, for example.

The first type of load change event may also be referred to as a ‘monitored load change event’. In which case, the change in the measured current may correspond to a change, or step change, of load on the electrical circuit provided by the one or more electrical loads in the monitored branch circuit if there is a (suitable) increase or decrease in the amplitude of the measured current between successive peaks, or successive peaks and troughs, in the measured current. The increase or decrease in the amplitude of the measured current may be greater than 5% of the amplitude of the measured current, for example.

The corresponding change in the measured voltage may correspond to a change of load on the electrical circuit provided by the one or more electrical loads in the monitored branch circuit if there is a (step or otherwise suitable) decrease or increase, respectively, in the amplitude of the measured voltage between successive peaks, or successive peaks and troughs, in the measured voltage. The change, or step change, in the measured voltage may occur simultaneously with, or during a period of time corresponding to, the change in the measured current. The significant increase or decrease in the amplitude of the measured voltage may be greater than 5% of the amplitude of the measured voltage, for example.

Accordingly, the first type of load change event may be detected based on the change between successive peaks, or between successive peaks and troughs, in the measured current. Additionally, the first type of load change event may be detected based on the change between successive peaks, or between successive peaks and troughs, in the measured voltage.

In an example, for the first type of load change event, the change in the measured current exceeds a threshold change of current. In other words, for a load change event of the first type to be detected, there must be a corresponding change in the measured current that exceeds the threshold change of current. The threshold change of current may be defined for a measured change of current between successive peaks, or successive peaks and troughs, in the measured current, for example. Alternatively, the threshold change of current may be defined for a prescribed period of time. The prescribed period of time may correspond to the time it takes for the current in each branch circuit of the electrical circuit to settle following a change of load on the electrical circuit provided by one or more of the plurality of electrical loads.

The threshold change of current may, for example, be configured to exceed: any change in the measured current originating in the supply of electrical power; and any change in the measured current corresponding to a change of load on the electrical circuit provided by one or more of the electrical loads in any of the plurality of branch circuits other than the monitored branch circuit. In this manner, changes in the measured current are effectively calibrated and such changes will not be erroneously detected as load change events of the first type.

Optionally, the estimation of the line impedance, RL, is determined according to the equation:

$$RL = \frac{- Δ {V}_{1}}{Δ {I}_{1}}$$

where RL is the estimated line impedance in the supply line; ΔV₁ is the change in the measured voltage corresponding to the detected load change event of the first type; and ΔI₁ is the change in the measured current corresponding to the detected load change event of the first type. Advantageously, in this manner, the estimation of the line impedance, RL, can be determined based upon measured changes in the monitored branch circuit, without need for measurements in the other branch circuits. In an example, ΔV₁ may take the form of the change, or step change, between successive peaks, or between successive peaks and troughs, in the measured voltage, which corresponds to the detected load change event of the first type. ΔI₁ may, for example, take the form of the change, or step change, between successive peaks, or between successive peaks and troughs, in the measured current, which corresponds to the detected load change event of the first type.

In an example, the method comprises: re-estimating the line impedance if: an additional load change event of the first type is detected; and the measured voltage associated with the additional load change event of the first type is greater than the measured voltage associated with the load change event upon which the current estimate of the line impedance is based. The re-estimation of the line impedance is based on the change in the measured current and the change in the measured voltage corresponding to the additional load change event of the first type. In this manner, the estimation of the line impedance is determined based on measured current and voltage changes when the aggregate electrical load of the plurality of electrical loads is smallest and, hence, the estimation of the line impedance is most accurate.

Optionally, the method comprises: detecting a second type of load change event if there is a change in the measured voltage that corresponds to a change of load on the electrical circuit provided by one or more of the plurality of electrical loads. The second type of load change event may also be referred to as a ‘non-monitored load change event’ or an ‘unmonitored load change event’. The change in the measured voltage may correspond to a change of load on the electrical circuit provided by one or more of the plurality of electrical loads if there is a suitable increase or decrease in the amplitude of the measured voltage between successive peaks, or between successive peaks and troughs, in the measured voltage. The increase or decrease in the amplitude of the measured voltage may be greater than 5% of the amplitude of the measured voltage, for example.

Optionally, a second type of load change event is detected if there is a change in the measured voltage that corresponds to a change of load on the electrical circuit provided by one or more of the plurality of electrical loads in one of the branch circuits other than the monitored branch circuit and there is a corresponding change in the measured current. In this example, for load change events of the second type, the corresponding change in the measured current does not correspond to a change of load on the electrical circuit provided by the one or more electrical loads in the monitored branch circuit. The first type of load change event may be distinguished from the second type of load change event in that the change in the measured current corresponding to the first type of load change event is greater than the change in the measured current corresponding to the second type of load change event.

For example, for the second type of load change event, the change in the measured current (corresponding to the change in the measured voltage) may be negligible. For example, the change in the amplitude of the measured current, between successive peaks, or between successive peaks and troughs, corresponding to a second type of load change event, may be a decrease or an increase of less than 5% of the amplitude of the measured current. In other words, the change in the measured current corresponding to a change of load on the electrical circuit provided by one or more of the plurality of electrical loads in one of the branch circuits other than the monitored branch circuit is much less than the change in the measured current corresponding to a change of load on the electrical circuit provided by the one or more electrical loads in the monitored branch circuit.

Optionally, for each of the first and second types of load change events, the change in the measured voltage exceeds a threshold change of voltage. The threshold change of voltage may be defined for a measured change of voltage between successive peaks, or between successive peaks and troughs, in the measured voltage, for example. Alternatively, or additionally, the threshold change of voltage may be defined for a prescribed period of time. The prescribed period of time may correspond to the time that it takes for the voltage in each branch circuit of the electrical circuit to settle following a change of load on the electrical circuit provided by one or more of the plurality of electrical loads.

The threshold change of voltage may be configured to exceed any changes in the measured voltage originating in the supply of electrical power, for example.

For example, each load change event, of the first or second type, may be indicative of an electrical appliance in the electrical circuit being switched between an off state and an on state. Load change events of the first type may be indicative of an electrical appliance in the monitored branch circuit being switched between an off state and an on state, whilst load change events of the second type may be indicative of an electrical appliance in one of the other branch circuits being switched between an off state and an on state.

In an example, the method comprises: estimating a total current in the electrical circuit, I_{supply}, according to the equation:

$${I}_{supply} = \frac{{V}_{supply} - {V}_{1}}{RL}$$

where I_{supply} is the total current in the electrical circuit; V_{supply} is the voltage of the supply of electrical power; V₁ is the measured voltage; and RL is the estimation of the line impedance; and using the estimated total current, I_{supply}, to estimate the total amount of power usage in the electrical circuit. In this manner, the total current in the plurality of branch circuits may be estimated based on voltage measurements from a single branch circuit, so that current sensors in the other branch circuits are not required.

Optionally, the total current in the electrical circuit, I_{supply}, may be estimated in response to (or in dependence on) detecting a load change event of the first or second type.

In an example, the method comprises: detecting a series of load change events, of the first and/or second type, over a period of time based on respective changes in the measured voltage; and estimating the total current in the electrical circuit, I_{supply}, in a step-wise manner that varies with time, wherein successive step changes in the total current in the electrical circuit, ΔIsupply, correspond to successive load change events in the series of load change events and each of the successive step changes in the total current in the electrical circuit, ΔIsupply, are estimated according to the equation:

$$Δ Isupply = \frac{- ΔV1}{RL}$$

where ΔIsupply is the step-change in the total current in the electrical circuit corresponding to one of the series of load change events; ΔV1 is the change in the measured voltage corresponding to that load change event; and RL is the estimation of the line impedance; and using the estimated total current, I_{supply}, to estimate the total amount of power usage in the electrical circuit. In this manner, changes in the total current and/or the total power may be estimated by aggregating the changes due to each load change event. In an example, ΔV1 may take the form of the change, or step change, between successive peaks, or between successive peaks and troughs, in the measured voltage, which corresponds to said load change event of the series of load change events.

Optionally, the estimate of the total power usage of the electrical circuit is based on the estimate of the total current and the measured voltage.

According to another aspect of the disclosure there is provided a non-transitory, computer-readable storage medium storing instructions thereon that when executed by a processor causes the processor to perform a method described in another aspect of the invention.

According to another aspect of the disclosure there is provided a control system of an electricity distribution apparatus for a plurality of electrical loads, the electricity distribution apparatus comprising an electrical circuit including: a plurality of branch circuits arranged in parallel, a current sensor arranged for measuring the current in a monitored branch circuit of the plurality of branch circuits, and a voltage sensor arranged for measuring the voltage across one of the plurality of branch circuits, wherein, in use, each branch circuit is coupled to one or more of the plurality of electrical loads and the electrical distribution apparatus is configured to distribute electrical power, received via a supply line from a supply of electrical power, across the electrical circuit, and wherein, in use, the control system is configured to estimate a total power usage of the electrical circuit according to a method described in a previous aspect of the invention.

It will be appreciated that preferred and/or optional features of each aspect of the disclosure may be incorporated alone or in appropriate combination in the other aspects of the invention also.

### BRIEF DESCRIPTION OF THE DRAWINGS

Examples of the disclosure will now be described with reference to the accompanying drawings, in which:

FIG. 1 shows a schematic view of an electrical circuit that is formed by an electricity distribution apparatus used to distribute a supply of electrical power to a plurality of electrical appliances in a building;

FIG. 2 shows the steps of a method for determining the power usage at the electricity distribution apparatus of FIG. 1;

FIG. 3 shows sub-steps of a first step of the method shown in FIG. 2;

FIG. 4 shows a plot of the magnitude of the current in a monitored branch circuit of the electricity distribution apparatus shown in FIG. 1 and a plot of the magnitude of the voltage across the monitored branch of the electricity distribution apparatus;

FIG. 5 shows sub-steps of a second step of the method shown in FIG. 2;

FIG. 6 shows a peak-to-peak current signal corresponding to the plot of current in FIG. 4 and a peak-to-peak voltage signal corresponding to the plot of voltage in FIG. 4;

FIG. 7 shows a magnified version of the example plot of the magnitude of the voltage across a monitored branch, shown in FIG. 4, indicating the peaks and troughs identified in the peak-to-peak voltage signal shown in FIG. 6;

FIG. 8 shows an example peak-to-peak voltage signal illustrating one or more load change events in the electrical circuit of FIG. 1;

FIG. 9 shows sub-steps of a third step of the method shown in FIG. 2 for determining a load change event in the operation of one or more of the plurality of electrical appliances in the electrical circuit of FIG. 1;

FIG. 10 shows an example simulation of a line impedance estimate obtained in the method shown in FIG. 2 and the variance in the error of said estimate over time as further load change events are detected; and

FIG. 11 shows an example plot of the total current in the branch circuits of the electricity distribution apparatus, shown in FIG. 1, obtained according to the method shown in FIG. 2.

### DETAILED DESCRIPTION

Embodiments of the disclosure relate to a method of determining a total amount of power used by the electrical appliances of a building based on the current and voltage in a single branch circuit, i.e. the monitored branch circuit, of an electricity distribution apparatus that distributes a supply of electrical power between the electrical appliances. Such methods involve measuring the voltage in one of the branch circuits and estimating a total amount of current passing through the various branch circuits using an estimation of the line impedance between the electricity distribution apparatus and the power source (which may be a power distribution network, for example). Thereafter, the total amount of power used by the electrical appliances may be determined based on the voltage measurement and the estimate of the total current.

Advantageously, determining the total current based on the estimation of the line impedance alleviates the need to measure the current in each branch circuit of the electricity distribution apparatus. Hence, the total power usage can be determined by an electricity distribution apparatus, even if the electricity distribution apparatus does not include a working current sensor in each branch circuit.

As shall become clear in the following description, example methods of the invention also determine, or refine, the estimation of the line impedance. In particular, the line impedance can be estimated by measuring the current in the monitored branch circuit and the voltage across one of the plurality of branch circuits when the electrical load in the monitored branch circuit changes, for example when an electrical appliances in the monitored branch circuit is switched on/off.

Such a change is identifiable because the voltage in each branch circuit of the electricity distribution apparatus will exhibit sharp sags and swells over time as the electrical appliances are switched on or off, changing the aggregate electrical load.

The corresponding voltage changes arise due to the impedance in the supply line that connects the power source to the electricity distribution apparatus, which effectively creates a voltage divider circuit, dividing the voltage of the electrical power supply between the electricity distribution apparatus and the supply line.

As the aggregate load varies over time, while the line impedance is relatively fixed, the voltage measured across the branch circuit of the electricity distribution apparatus will vary proportionately to changes in the aggregate electrical load. Hence, the methods of this invention use this phenomenon to identify a change in the state of operation of an electrical appliance in the monitored branch circuit and refine the estimation of the line impedance. In turn, refining the estimate of the line impedance provides for an improved estimate of the total current flowing into the building, and the corresponding power usage.

It is anticipated that the invention will enable a reduction in the cost of instrumentation of low voltage electrical systems in buildings or elsewhere. Such advantages arise from the ability to determine the total current flowing into the building, and the corresponding power usage of the electrical appliances of the building based on current measurements from a single branch circuit.

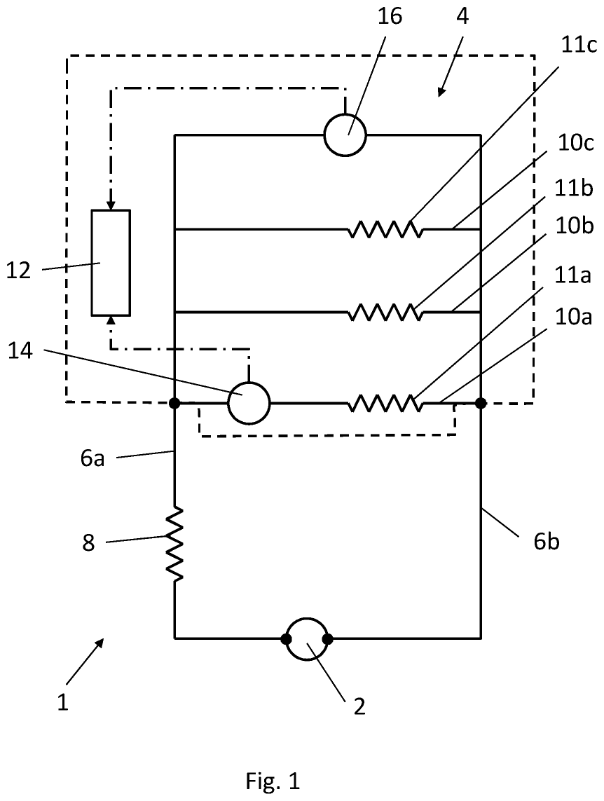

FIG. 1 schematically illustrates an example electrical circuit 1 for supplying electrical power to a plurality of electrical appliances of a building. The electrical circuit 1 features a power source 2, an electricity distribution apparatus 4 and a supply line 6.

The power source 2 provides a supply of electrical power intended to power the operation of the electrical appliances of the building. In this example, the power source 2 is provided by a power distribution network. More specifically, the power source 2 may correspond to the power output from the transformer of the power distribution network that is nearest to the building. Accordingly, in this example, the power source 2 supplies electrical power to the electrical circuit 1 that comprises an alternating current and an alternating voltage. It shall be appreciated that, in other examples, the power source may take other forms.

For the purposes of the following description it is assumed that the alternating current provided by the power source 2 has a constant amplitude and frequency. However, the skilled person would appreciate that the alternating electrical power provided by a distribution network is subject to time-varying fluctuations, originating in the distribution grid. Such fluctuations may, for example, cause the magnitude of the alternating current to increase and/or decrease by less than 5%. In particular, the fluctuations may cause the magnitude of the alternating current to increase and/or decrease by less than 2%. Herein such variations in the supply of electrical power are referred to as supply power fluctuations.

In FIG. 1, the supply line 6 is illustrated schematically by a pair of lines 6a and 6b extending between respective points of connection to the power source 2 and the electricity distribution apparatus 4. In this manner, the supply line 6 electrically connects the power source 2 to the electricity distribution apparatus 4, conducting electricity through the supply line 6 to the electricity distributions apparatus 4 in order to power the electrical appliances of the building.

The supply line 6 may, for example, take the form of a service entrance, connecting a drop line from the distribution network, or the transformer, to the electricity distribution apparatus 4. In FIG. 1, the line impedance of the supply line 6 is represented schematically by a resistor 8 arranged on the supply line 6, between the power source 2 and the electricity distribution apparatus 4.

In this example, the electricity distribution apparatus 4, takes the form of a panel board, but it shall be appreciated that, in other examples, the electricity distribution apparatus may take other forms suited to the power distribution requirements of the building, such as a distribution board, a breaker panel, or an electric panel.

The electricity distribution apparatus 4 comprises a plurality of branch circuits 10a-c that connect to the electrical appliances of the building and a control system 12 configured to determine the power usage of the plurality of branch circuits 10a-c. The plurality of branch circuits 10a-c are arranged in parallel, with each branch circuit 10a-c originating and terminating at the connection of the electricity distribution apparatus 4 to the supply line 6.

In this example, the plurality of branch circuits 10a-c includes a first branch circuit 10a, a second branch circuit 10b and a third branch circuit 10c. For the sake of simplicity, each of the plurality of branch circuits 10a-c is connected to one electrical appliance of the building and the electrical load corresponding to the operation of each electrical appliance is represented schematically in FIG. 1 by a respective resistor 11a-c arranged in each branch circuit 10a-c. Each branch circuit 10a-c also includes a respective switch (not shown) for selectively changing the state of the respective electrical appliance between an on state and an off state.

To give some context to the following description, in this example, the electrical load 11a corresponding to the electrical appliance in the first branch circuit 10a has a resistance of 15 Ohms and draws power when said electrical appliance is switched on, but draws no power when the electrical appliance is switched off. Similarly, the electrical load 11b corresponding to the electrical appliance in the second branch circuit 10b has a resistance of 20 Ohms and draws power when the electrical appliance in the second branch circuit 10b is switched on, but draws no power when said electrical appliance is switched off. The electrical load 11c corresponding to the electrical appliance in the third branch circuit 10c has a resistance of 25 Ohms and draws power when the electrical appliance in the third branch circuit 10c is switched on, but draws no power when said electrical appliance is switched off.

It shall be appreciated that, in other examples, the plurality of branch circuits may include any number of branch circuits and each of the plurality of branch circuits may be connected to one or more electrical appliances, each forming a respective electrical load in said branch circuit or collectively forming an aggregate electrical load in said branch circuit.

The electricity distribution apparatus 4 includes at least one voltage sensor configured to measure the voltage across one of the plurality of branch circuits 10a-c and to output a signal indicative of the measured voltage to the control system 12. As noted previously, the voltages are equal across the branch circuits so, in this example, the electricity distribution apparatus 4 includes a single voltage sensor 16 that is configured to measure the voltage across the third branch circuit 10c, as shown in FIG. 1. It shall be appreciated that the voltage measured across the third branch circuit 10c will be equal to the voltage across the first branch circuit 10a and the voltage across the second branch circuit 10b, due to the parallel arrangement.

As shown in FIG. 1, in this example, the first branch circuit 10a is a ‘monitored branch circuit’ that includes a current sensor 14 configured to measure the current passing therethrough and output a signal indicative of the measured current to the control system 12. In other words, the first branch circuit 10a is designated as the ‘monitored branch circuit’ because it includes the current sensor 14, which is configured to measure the current in the first branch circuit 10a and communicate the measured current to the control system 12. Notably only one of the plurality of branch circuits 10a-c in this example includes a working current sensor 14.

In general, the monitored branch circuit 10a, i.e. the branch circuit in which a current sensor 14 is connected, is selected from the plurality of branch circuits 10a-c during the connection of the electricity distribution apparatus 4 to the electrical appliances of the building. The selection, i.e. the choice of which branch circuit to connect to the current sensor 14, is important. Specifically, the monitored branch circuit 10a may be selected from the plurality of branch circuits 10a-c on the basis that the electrical appliances, or electrical loads, in said branch circuit are likely to be switched on/off in isolation, i.e. no other electrical appliances/loads are switched on/off respectively in other branches during the same period.

Accordingly, the monitored branch circuit may be selected from the plurality of branch circuits 10a-c based on one or more of the following factors: the number of electrical appliances in each branch circuit (which may be minimised in the monitored branch circuit); the magnitude of the electrical load in each branch circuit (which may be maximised in the monitored branch circuit); and the frequency with which the electrical appliances in each branch circuit change state (which may be configured to maximise the likelihood that the electrical appliances in the monitored branch circuit will change between an on and an off state, whilst the electrical appliances in the other branch circuits are all in an off state).

In other examples, the electricity distribution apparatus may include a current sensor in each branch circuit, as in a conventional panel board. In which case, a monitored branch circuit may be selected from the plurality of branch circuits manually or the electricity distribution apparatus may be configured to electronically select a monitored branch circuit from the plurality of branch circuits, for example under certain conditions. For example, if the current sensor in one of the plurality of branch circuits fails, such that it is not possible to determine the power usage in each branch circuit, a control system of the electricity distribution apparatus may be configured to designate one of the branch circuits as the monitored branch circuit. For example, the control system may select the monitored branch circuit may on the basis of any of the factors described above. The designated branch circuit would include a working current sensor and the control system may proceed to determine the total power usage of the plurality of branch circuits in accordance with the methods of the present invention described herein.

In this manner, it shall be appreciated that example methods of the present invention are applicable to the electricity distribution apparatus 4, shown in FIG. 1, and to the conventional electricity distribution apparatus, described above, which includes a current sensor in each branch circuit.

The control system 12 may include one or more controllers configured to receive the signal indicative of the current in the first branch circuit 10a from the current sensor 14; receive the signal indicative of the voltage across one of the plurality of branch circuits 10a-c from the voltage sensor 16; and determine, in accordance with the methods of the present invention: a total amount of current in the plurality of branch circuits; an estimation of the line impedance between the power source 2 and the plurality of branch circuits 10a-c; and/or a total amount of power usage of the plurality of branch circuits 10a-c; in dependence on the first and second signals. The control system 12 may also be configured to output the total amount of power usage of the plurality of branch circuits 10a-c to enable more sophisticated energy disaggregation strategies.

For purposes of this disclosure, it is to be understood that the controller(s) described herein can each comprise a control unit or computational device having one or more electronic processors. A set of instructions could be provided which, when executed, cause said controller(s) or control unit(s) to implement the control techniques described herein (including the described method(s)). The set of instructions may be embedded in one or more electronic processors, or alternatively, the set of instructions could be provided as software to be executed by one or more electronic processor(s). The set of instructions may be embedded in a computer-readable storage medium (e.g., a non-transitory computer-readable storage medium) that may comprise any mechanism for storing information in a form readable by a machine or electronic processors/computational device, including, without limitation: a magnetic storage medium (e.g., floppy diskette); optical storage medium (e.g., CD-ROM); magneto optical storage medium; read only memory (ROM); random access memory (RAM); erasable programmable memory (e.g., EPROM and EEPROM); flash memory; or electrical or other types of medium for storing such information/instructions.

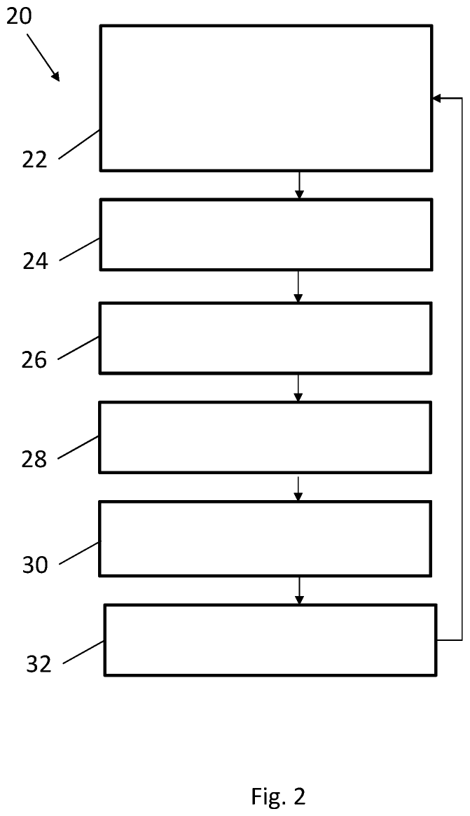

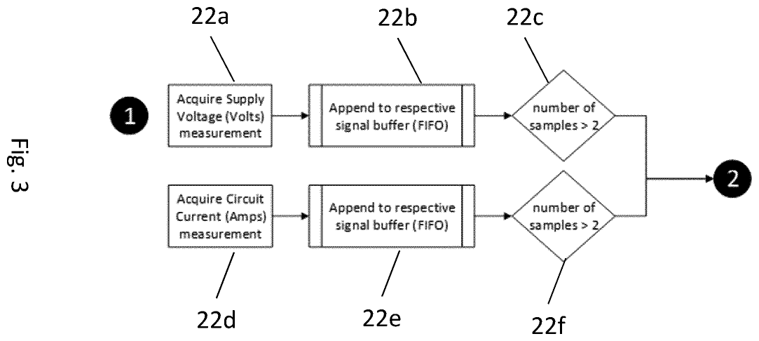

An example method 20 of determining the power usage of the plurality of branch circuits 10a-c shall now be described with reference to FIG. 2, which schematically illustrates the method 20, and with additional reference to FIGS. 3 to 13, which support the description of the method 20.

It shall be appreciated that the method 20 comprises a plurality of steps for determining the total power usage of the plurality of branch circuits 10a-c, which varies with time, and although the method 20 has a generally sequential manner, it shall be appreciated that one or more of the plurality of steps may be executed more than once and/or simultaneously with other steps of the method 20.

In step 22, the method 20 includes determining the current in the monitored branch circuit 10a and determining the voltage across one of the branch circuits 10a-c.

In this example, the current in the monitored branch circuit 10a is measured using the current sensor 14 and the voltage sensor 16 measures the voltage across the third branch circuit 10c. The current measurements and the voltage measurements may each be sampled at a sufficient rate to accurately capture the waveform of the supply of electrical power. For example, the current measurements and the voltage measurements may each be sampled at a rate of 4 kHz for a supply of electrical power from the power distribution network of the United Kingdom.

The voltage and current measurements are stored in a buffer such that a series of buffered voltage measurements may form a voltage waveform and a series of buffered current measurements may form a current waveform. For example, each sampled current measurement may be output from the current sensor 14 to the control system 12 and each sampled voltage measurement may be output from the voltage sensor 16 to the control system 12. The control system 12 may store each current measurement and each voltage measurement in a memory device (not shown) of the control system 12 with a respective timestamp that may be used to form the voltage waveform and/or the current waveform.

This process is illustrated schematically in FIG. 3, which shows: acquiring a voltage measurement in step 22a; appending the voltage measurement to the buffer in step 22b; and deciding, in step 22c, whether to proceed to step 24 if at least two voltage measurements are stored in the buffer. FIG. 3 also shows: acquiring a current measurement in step 22d; appending the current measurement to the buffer in step 22e; and deciding, in step 22f, whether to proceed to step 24 if at least two current measurements are stored in the buffer

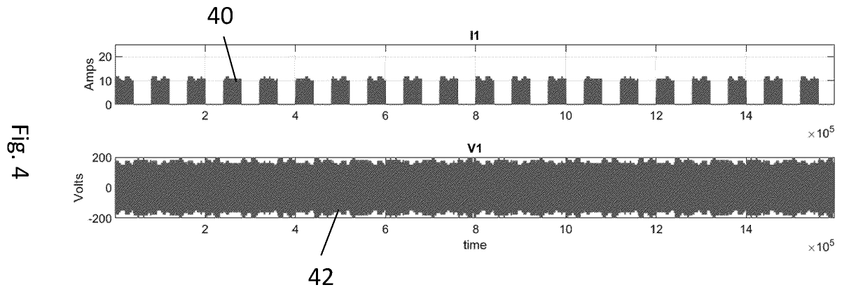

FIG. 4 illustrates an example current waveform 40 produced by plotting the absolute value of the current measurements stored in the buffer and an example voltage waveform 42 produced by plotting the absolute value of the voltage measurements stored in the buffer during the same period of time as the current measurements.

As shown, the example current waveform 40 shows periods of 0 Amps, when the electrical appliance in the first branch circuit 10a is switched off, and periods of non-zero current, when the electrical appliance in the first branch circuit 10a is switched on. The pattern defined by the voltage waveform 42 shall become clear in the following description.

Once a plurality of current measurements and a plurality of voltage measurements have been determined and stored in the buffer, forming the current and voltage waveforms, the method 20 can proceed to step 24.

It shall be appreciated that further measurements may be appended to the respective waveforms as the method 20 proceeds through the subsequent steps.

In step 24, the method 20 includes determining the peaks and troughs of the voltage waveform based on the buffered voltage measurements and determining the peaks and troughs of the current waveform based on the buffered current measurements.

As shall be appreciated by the skilled person, the peaks and troughs of the voltage and current waveforms may be determined by various analytical methods. Hence, the following example is not intended to be limiting on the scope of the invention.

For each waveform, the peaks and troughs may, for example, be detected by determining the forward difference between successive measurements. For example, a peak may be identified if the forward difference between a first measurement and a second consecutive measurement is greater than zero, (indicating positive or upwards slope) and the forward difference between the second measurement and a third consecutive measurement is less than or equal to 0 (indicating flat or decreasing slope).

Where the absolute values or Root Mean Square (RMS) values of the current/voltage measurements are used, a trough may be detected in the same manner as the peaks. Alternatively, troughs may, for example, be detected if the forward difference between the first and second consecutive measurements is less than zero, and the forward difference between the second and third consecutive measurements is equal to or greater than zero.

It shall be appreciated that the peaks and troughs in the voltage waveform should substantially correspond to the peaks and troughs in the current waveform, with the exception of periods during which the electrical load in the monitored branch circuit 10a is zero (since the current also falls to zero).

In some examples, to limit the search, and reduce the computational complexity of determining the peaks and troughs, successive current measurements may only be compared to identify a peak/trough if the current is larger than a peak current threshold. Similarly, successive voltage measurements may only be compared to identify a peak/trough if the voltage is larger than a peak voltage threshold. In such examples, setting a suitable peak current threshold and a suitable peak voltage threshold may rely on knowledge of the voltage and/or current amplitude of the supply of electrical power from the power source 2. For example, if the supply of electrical power is 240 volts, then the peak voltage threshold may be 200 volts.

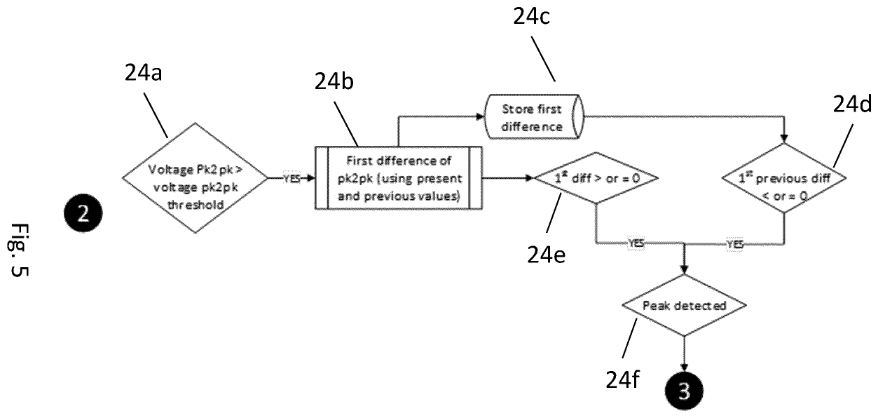

For the sake of clarity, the step-by-step process of determining the peaks of the voltage waveform is illustrated schematically in FIG. 5. In step 24a a first voltage measurement and a second consecutive voltage measurement are compared to the peak voltage threshold, if the first and second voltage measurements exceed the peak voltage threshold then the forward difference between the first and second measurements is determined in step 24b and stored in the buffer in step 24c. Steps 24a and 24b are then repeated for the second voltage measurement and a third consecutive voltage measurement. In step 24d, it is determined whether the forward difference between the first and second voltage measurements (stored in the buffer) is greater than or equal to zero and, in step 24e, it is determined whether the forward difference between the second and third voltage measurements is less than or equal to zero. If steps 24d and 24e are satisfied then a peak is detected in step 24f.

In other examples, backward difference or other methods of determining the peaks and trough of the current and/or voltage waveforms may be used, as shall be appreciated by the skilled person.

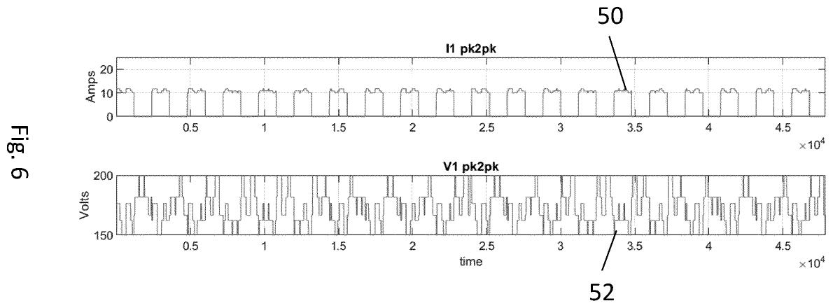

In any case, when arranged in series, the detected peaks and troughs of the voltage waveform form a peak-to-peak voltage signal and the detected peaks and troughs of the current waveform form a peak-to-peak current signal. An example peak-to-peak current signal 50, in which absolute values of the current measurements are used, is shown in FIG. 6 alongside an example peak-to-peak voltage signal 52, in which absolute values of the voltage measurements are used. The peak-to-peak current signal 50 is shown for the same period of time as the peak-to-peak voltage signal 52.

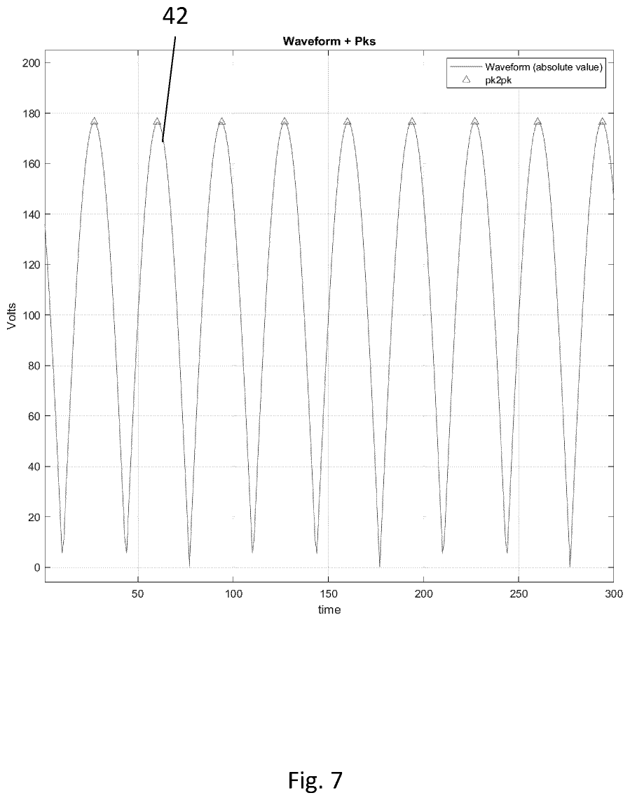

For enhanced detail, FIG. 7 illustrates a magnified version of the voltage waveform 42, shown in FIG. 4, indicating the identified peaks and troughs.

As shall become clear in the following description, the power usage of the electrical appliances changes with the aggregate electrical load and the electrical load in each branch circuit 10a-c changes in dependence on the operational state of the electrical appliances in said branch circuit. For example, when one of the electrical appliances in a branch circuit 10a-c is switched on or off, the electrical load in the respective branch circuit 10a-c increases or decreases in a corresponding manner. Hence, it is useful to detect changes in the operational states of the electrical appliances for the purpose of determining the total power usage. In the following description, each change in the operational state of an electrical appliance in one of the plurality of branch circuits 10a-c is referred to as a ‘load change event’.

Furthermore, for the purposes of estimating the line impedance in the supply line 6, it is also particularly useful to identify a particular type of load change event corresponding to a change of the electrical load in the monitored branch circuit 10a. In the following description, each change in the operational state of an electrical appliance in the monitored branch circuit 10a is referred to as a ‘monitored load change event (MLCE)’.

Accordingly, in step 26, the method 20 includes detecting one or more load change events of a first type, in which there is a change in the operational state of an electrical appliance in one of the plurality of branch circuits 10a-c, and detecting one or more load change events of a second type, i.e. the MLCEs.

When the electrical load of any branch circuit 10a-c increases, there is a sharp, corresponding, decrease in the measured voltage. Conversely, there is a sharp increase in the measured voltage whenever the electrical load of any branch circuit 10a-c decreases.

The measured current will also increase suddenly if the electrical load of any branch circuit 10a-c increases and the measured current will decrease suddenly if the electrical load of any branch circuit 10a-c decreases.

In this manner, each load change event is characterised by a rapid change of current/voltage that differs characteristically from the random current variations due to the supply power fluctuations described previously.

Furthermore, the current in each branch circuit 10a-c depends on the respective electrical load of that branch circuit 10a-c. Hence, if the electrical load of the monitored branch circuit 10a increases, the measured current will increase by a greater amount compared to the change in the measured current corresponding to an increase of the electrical load in one of the other branch circuits 10b-c. Similarly, the measured current will decrease by a greater amount if the electrical load of the monitored branch circuit 10a decreases, compared to a corresponding decrease of the electrical load in one of the other branch circuits 10b-c.

Hence, load change events due to a change in the electrical load of the monitored branch circuit 10a, i.e. MLCEs, are distinguishable from load change events due to a change in the electrical load of one of the other branch circuits 10b-c.

Accordingly, in step 26, the method 20 may detect the one or more load change events, and/or MLCES, by analysing changes in the measured current and the measured voltage.

It shall be appreciated that changes in the voltage and/or current measurements corresponding to an electrical appliance being switched on/off may be determined by various analytical methods. Hence, the following example is provided for the sake of clarity and is not intended to be limiting.

In an example, the load change events, including the MLCEs, are detected, in step 26, by determining the forward or backward difference between successive peaks and troughs in the peak-to-peak voltage signal 52 and/or the peak-to-peak current signal 50. Any changes in the peak-to-peak signals are compared to respective thresholds that may be configured to signify a load change event, such as a MLCE, as opposed to a random fluctuation in the supply of electrical power from the power source 2.

For example, a load change event may be detected if there is a sharp or stepwise voltage change between a peak and a trough that exceeds a respective voltage difference threshold. Alternatively, or additionally, a load change event may be detected if there is a sharp or stepwise current change between a peak and a trough that exceeds a respective current difference threshold.

The voltage difference threshold and the current difference threshold should each be large enough to filter out the supply power fluctuations, i.e. the spurious changes in voltage/current due to the distribution grid noise. For example, the voltage difference threshold may be less than or equal to 5% of the maximum voltage in the peak-to-peak voltage signal 52 or the amplitude of the voltage from the power source 2. Similarly, the current difference threshold may be less than or equal to 5% of the maximum current in the peak-to-peak current signal 50 or the amplitude of the current from the power source 2.

In general, load change events may be indicated by changes in the measured current and/or the measured voltage. However, in order to easily detect MLCEs, the current difference threshold may be configured to filter out load change events due to changes in the state of the electrical appliances in unmonitored branch circuits 10b-c, i.e. in branch circuits 10b-c other than the monitored branch circuit 10a. This is made possible because the change in current due to a load change event in the monitored branch circuit 10a is much larger than the change in current due to a load change event on another branch circuit 10b-c. Such a current difference threshold may, for example, be determined empirically.

In this manner, the voltage difference threshold may be configured to identify load change events in any branch circuit, whilst the current difference threshold may only be configured to identify load change events in the monitored branch circuit 10a.

Hence, in step 26, the method 20 may proceed to determine the load change events, and the MLCEs, from the peak-to-peak voltage signal 52 and the peak-to-peak current signal 50 as described in the following.

An electrical appliance being switched on in one of the plurality of branch circuits 10a-c) is indicated if the peak-to-peak voltage signal 52 decreases between a peak and a consecutive trough and the difference between the peak and the trough is greater than the threshold voltage difference. In which case, a load change event referred to as a ‘voltage on event’ may be flagged.

An electrical appliance being switched off in any of the plurality of branch circuits 10a-c) is indicated if the peak-to-peak voltage signal 52 increases between a peak and a consecutive trough and the difference between the peak and the trough is greater than the threshold voltage difference. In which case, a load change event referred to as a ‘voltage off event’ may be flagged.

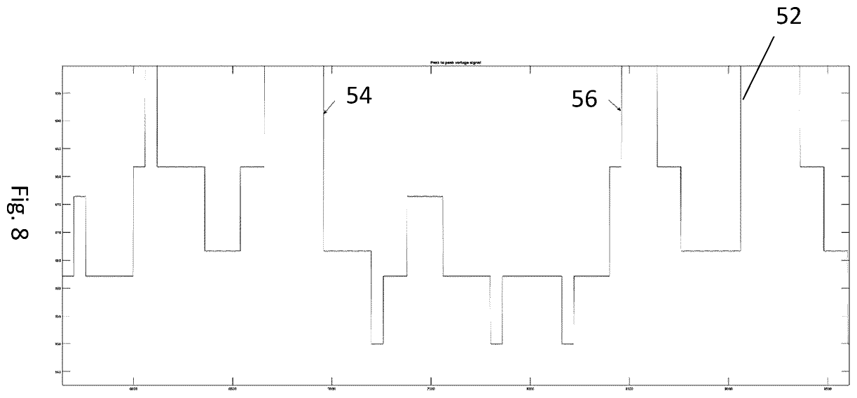

By way of example, FIG. 8 illustrates an example peak-to-peak voltage signal 52 in which a voltage on event 54 is marked after a sharp decrease in the peak-to-peak voltage signal 52 and a subsequent voltage off event 56 is marked after a sharp increase in the peak-to-peak voltage signal 52.

An electrical appliance in the monitored branch circuit 10a being switched on is indicated if the peak-to-peak current signal 50 increases between a peak and a consecutive trough and the difference between the peak and the trough is larger than the threshold current difference. In which case, a load change event referred to as a ‘current on event’ may be flagged.

An electrical appliance in the monitored branch circuit 10a being switched off is indicated if the peak-to-peak current signal 50 decreases between a peak and a consecutive trough and the difference between the peak and the trough is larger than the threshold current difference. In which case, a load change event referred to as a ‘current off event’ may be flagged.

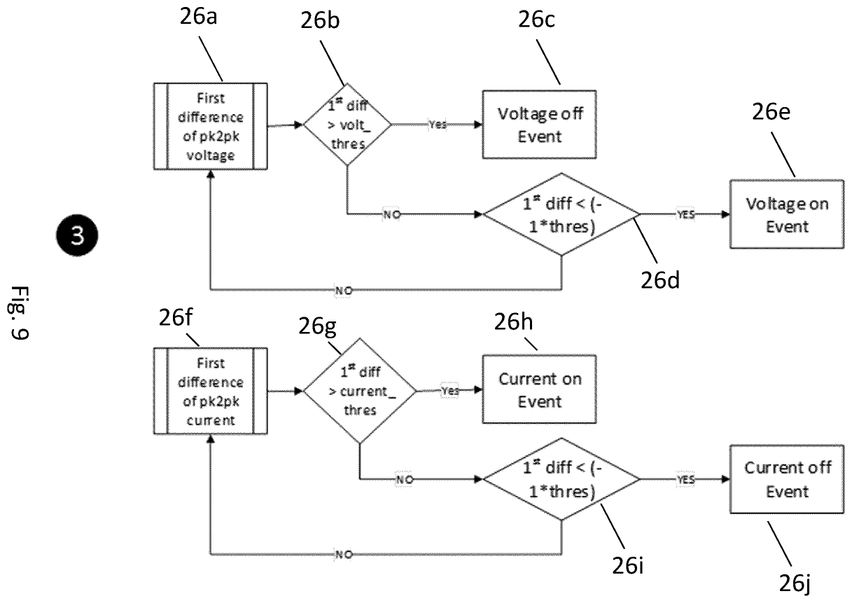

For the sake of clarity, the step-by-step process of determining the load change events is illustrated schematically in FIG. 9, which shows: determining the forward difference between the absolute values of a peak and a consecutive trough of the peak-to-peak voltage signal 52 in step 26a and determining if the forward difference is larger than the threshold voltage difference in step 26b. If the forward difference is larger than the threshold voltage difference, then a voltage off event is flagged in step 26c. If the forward difference is less than the threshold voltage difference, then it is determined whether the forward difference is less than a negative threshold voltage difference, in step 26d. If the forward difference is less than the negative threshold voltage difference, then a voltage off event is flagged in step 26e.

FIG. 9 also shows determining the forward difference between the absolute values of a peak and a consecutive trough of the peak-to-peak current signal 50 in step 26f and determining if the forward difference is larger than the threshold current difference in step 26g. If the forward difference is larger than the threshold current difference, then a current on event is flagged in step 26h. If the forward difference is less than the threshold current difference, then it is determined whether the forward difference is less than a negative threshold current difference, in step 26i. If the forward difference is less than the negative threshold current difference, then a current on event is flagged in step 26j.

In some examples, each load change event may also be verified by monitoring whether the voltage and/or current is steady after the detected load change event. For example, steadiness may be determined by comparing the latter peak/trough of the current/voltage to one or more subsequent peaks/trough of the current/voltage to determine whether the change is transient, and possibly due to noise, or longer lasting and more likely corresponding to an appliance on/off event. A transient change may last less than 5 seconds, for example. Similarly, a steady state algorithm may be used that incorporates a steady state delay, which forces the algorithm to record current and voltage changes a small period, e.g. 5 seconds, after an initial load change event is detected such that the voltage/current changes correspond to the steady state of the changed electrical load.

Over time, as the electrical appliances of the building are switched on/off a plurality of each of these load change events will be detected in step 26.

It shall be appreciated that a simultaneous voltage on event and current on event or a simultaneous voltage off event and current off event will indicate a load change event in the monitored branch circuit 10a, i.e. an MLCE. In contrast, a voltage on event or a voltage off event with no corresponding current on or current off event will indicate a load change event in one of the other branch circuits 10b-c.

For each MLCE, the absolute value of the peak-to-peak voltage signal 52 may also be stored in a buffer for subsequent use in determining the estimation of the line impedance. For example, the absolute value of the peak-to-peak voltage signal 52 at the start of each MLCE may be stored in the memory storage device of the control system 12. These absolute values are referred to as the voltages of the respective MLCEs in the following description and use of these values shall become clear in a later part of the description.

As shall become clear in the following description, when an MLCE occurs in isolation, i.e. whilst the electrical loads in the other branch circuits are substantially constant, the resulting change in the measured voltage is negatively proportional to the change in the measured current. Furthermore, the proportionality constant between the change in the measured voltage and the change in the measured current corresponds to the line impedance in the supply line 6, i.e. the line impedance between the power source 2 and the plurality of branch circuits 10a-c.

Hence, in step 28, the method 20 includes determining an estimation of the line impedance based on the current and voltage changes measured in the monitored branch circuit 10a due to an MLCE detected in step 26. This process and the principles employed shall be explained in more detail in the following description.

It shall be appreciated that the first, second and third branch circuits 10a-c of the electricity distribution apparatus 4 have currents I1, I2 and I3 and voltages V1, V2 and V3 respectively. The voltage, V3, across the third branch circuit 10c is measured by the voltage sensor 16 and the voltages V1, V2, and V3 across each branch circuit 10a-c are equal to one another due to the parallel arrangement.

The current, I1, in the first branch circuit 10a is measured by the current sensor 14, but the currents I1, I2 and I3 in each branch circuit 10a-c are not equal. Instead, the currents I1, I2 and I3 conducted through the branch circuits 10a-c sum together to give a total current, I_{supply}.

The total current, I_{supply}, in the plurality of branch circuits 10a-c, is equal to the current conducted along the supply line 6 and, as noted previously, the impedance in the supply line 6 effectively creates a voltage divider circuit, dividing the voltage of the power source 2 between the plurality of branch circuits 10a-c and the supply line 6 itself. The line impedance is relatively fixed and may be considered constant.

Accordingly, the total current, I_{supply}, can be determined according to the equation:

Isupply(t)=Vsupply−V1(t)/RL (1)

where t reflects the time-varying nature of the total current, I_{supply}; Vsupply is the voltage of the electrical power supplied by the power source 2; V1(t) is the time-varying voltage across the monitored branch circuit 10a, which is equal to the time-varying voltage V3(t) measured by the voltage sensor 16; and RL is the line impedance of the supply line 6.

For the sake of simplicity, inductive loads are not accounted for in this example and the electrical circuit 1 is assumed to be purely resistive, i.e. no reactive power. This approach is readily generalizable.

If the electrical load in one of the plurality of branch circuits 10a-c changes, for example due to an electrical appliance being switched on or off (i.e. due to a load change event), then there will be a corresponding change in the total current, I_{supply}. Alternatively phrased, the total current, I_{supply}, changes in dependence on each load change event identified in step 26. The resulting change to the total current, I_{supply}(t), denoted by ΔI_{supply}, can be determined according to the following equations:

$$Isupply ( t ) + Δ Isupply = \frac{V supply - V 1 ( t ) - Δ V 1}{RL} \qquad ( 2 )$$

$$Δ Isupply = \frac{- ΔV1}{RL} \qquad ( 3 )$$

where ΔV1 is the change in voltage across one of the plurality of branch circuits 10a-c corresponding to the load change event. Hence, the line impedance, RL, can be determined from ΔI_{supply} and ΔV1.

Furthermore, if the change in the total current, ΔI_{supply}, is due to a change in the electrical load of the monitored branch circuit 10a, and in particular, due to an isolated MLCE, then the change in the total current ΔI_{supply} may be considered equal to the change in the current, ΔI1, in the monitored branch circuit 10a. This gives the following equation:

$$RL = \frac{( - ΔV1 )}{Δ I 1} \qquad ( 4 )$$

As such the line impedance can be estimated based on the voltage and current changes in the monitored branch circuit 10a that arise due to an MLCE.

Hence, in an example, step 28 involves determining the estimation of the line impedance, RL, according to Equation 4, where ΔV1 is the step change (or voltage difference) in the peak-to-peak voltage signal 52 corresponding to an MLCE detected in step 26 and ΔI1 is the step change (or current difference) in the peak-to-peak current signal 50 corresponding to the MLCE.

It shall be appreciated that estimating the line impedance, RL, according to Equation 4, relies on an assumption that the electric loads (and hence the current) in the unmonitored branch circuits 10b-c, are constant during the MLCE. In practice such conditions may be relatively uncommon in a given building and it may be unlikely that the electric loads (and hence the current) in the unmonitored branch circuits 10b-c remain constant during a randomly selected MLCE.

Hence, some examples of the invention include additional measures, in step 28, for maximizing the accuracy of the estimate of the line impedance, RL, based on the available data.

In particular, in accordance with Equation 4, the estimate of the line impedance, RL, is most accurate when the electrical load of the monitored branch circuit 10a is most dominant. For example, this may be the case when the electrical appliances in the other branch circuits 10b-c are switched off, producing minimal electrical load.

Furthermore, the absence of electrical loads in the other branch circuits 10b-c can be inferred from the voltage measurements. For example, the measured voltage is maximised when the aggregate electrical load is minimised.

Accordingly, in some examples, whenever an MLCE is detected in step 26, the method 20 may determine the estimate of the line impedance, RL, in two stages. In a first stage, the voltage of the newly detected MLCE may be compared to the voltage of the MLCE upon which the estimate of the line impedance, RL, is based.

In a second stage, the estimate of the line impedance, RL, may be recalculated according to Equation 4, based on the newly detected MLCE, if the voltage of the newly detected MLCE is larger than the voltage of the MLCE previously used to determine the estimate of the line impedance, RL.

When comparing the voltages of the newly detected MLCE and the MLCE previously used to determine the estimate of the line impedance, RL, it may be preferable to compare the respective voltages of the peak-to-peak voltage signal 52 at the beginning of (or immediately prior to) each MLCE, for consistency.

Furthermore, when recalculating the estimate of the line impedance, RL, based on the newly detected MLCE, it shall be appreciated that ΔV1, in Equation 4, is the step change (or voltage difference) in the peak-to-peak voltage signal 52 corresponding to the newly detected MLCE. Similarly, ΔI1, in Equation 4, is the step change (or current difference) in the peak-to-peak current signal 50 corresponding to the newly detected MLCE.

Over time, an increasing number of MLCEs will be detected as the electrical appliance in the monitored branch circuit 10a is switched on and off and it is assumed that the electrical load on the monitored branch circuit 10a will eventually be activated in isolation (with a maximum measured voltage). The MLCE corresponding to this action will be detected, in step 26, and used to determine the estimate of the line impedance, RL, in step 28, so that the error in the estimate of the line impedance, RL, will eventually reduce to zero.

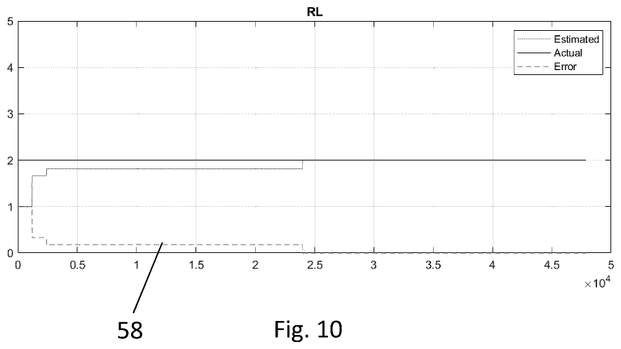

By way of example, FIG. 10 shows an example plot of the error 58 in the estimation of the line impedance, RL, over time. As shown, the error 58 reduces in step changes as MLCEs occur at higher voltages, i.e. with smaller aggregate electrical loads. Eventually the error 58 reduces to zero, or a negligible amount, after an MLCE occurs in isolation.

In step 30, the method 20 includes determining the total current, I_{supply}, in the plurality of branch circuits 10a-c using the estimation of the line impedance, RL, and the voltage across one of the plurality of branch circuits 10a-c (as measured by the voltage sensor 16).

The skilled person shall appreciate that, once an estimate of the line impedance, RL, has been determined, in step 28, there are various methods for determining the total current, I_{supply}, in the plurality of branch circuits 10a-c. Accordingly, the following examples are not intended to be limiting on the scope of the invention.

In an example, the total current, I_{supply}, may be determined, in step 30, according to Equation 1, where Vsupply is the voltage amplitude of the electrical power supplied by the power source 2; V1(t) is defined by the peak-to-peak voltage signal 52 determined in step 24; and RL is the line impedance of the supply line 6.

In another example, it may be assumed that the total current, I_{supply}, is constant between the load change events detected in step 26. In which case, the total current, I_{supply}, may be determined, in step 30, according to Equation 1, where Vsupply is the voltage amplitude of the electrical power supplied by the power source 2; V1(t) is a series of voltages corresponding to the measured voltage after each load change event detected in step 26; and RL is the line impedance of the supply line 6.

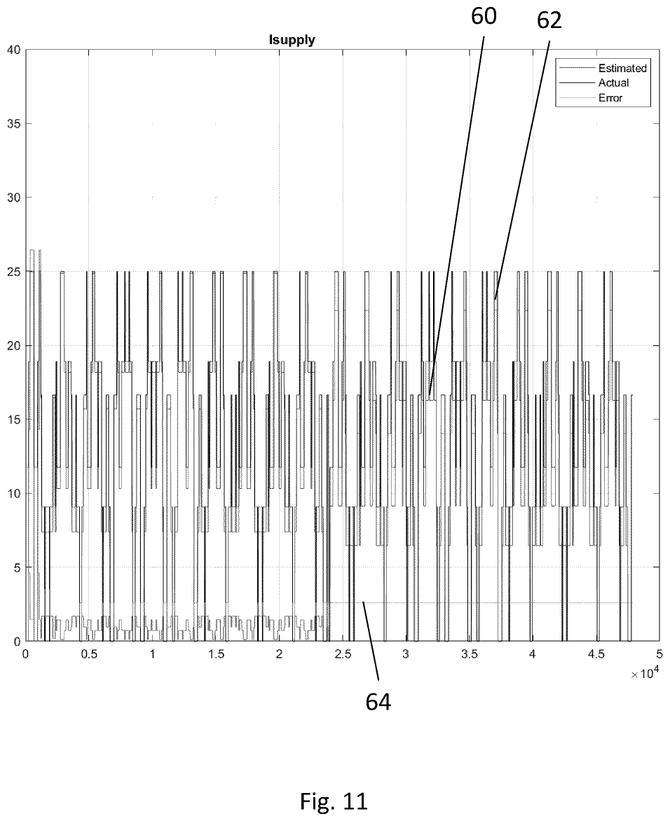

In this example, the total current, I_{supply}, forms a total current signal 60 that has a step-wise, or digital manner, as shown in the example in FIG. 11. In FIG. 11, the current signal 60 is shown alongside the actual total current 62 and the error in the estimate 64.

It shall be appreciated that the total current, I_{supply}, may be determined in an equivalent manner by determining the change in the total current, ΔI_{supply}, for each load change event detected in step 26 and then accumulating the changes in the total current, ΔI_{supply}, over time to determine the total current, I_{supply}, in step 30.

In which case, for each load change event detected in step 26, the change in the total current, ΔI_{supply}, may be determined according to Equation 2, where ΔV1 is the change in the peak-to-peak voltage signal 52 corresponding to the respective load change event. It follows that the total current, I_{supply}, may then be determined according to Equation 1 by assuming that the total current, I_{supply}, is constant between the load change events.

It shall be appreciated that the total power usage, P, in the plurality of branch circuits 10a-c is equal to the voltage across one of the plurality of branch circuits 10a-c multiplied by the total current, I_{supply}, as described by the following Equation:

P=V1·I1+V2·I2+V3·I3=V1·(I1+I2+I3)=V1·I_{supply} (5)

Hence, in step 32, the method 20 determines the total amount of power usage, P, at the plurality of branch circuits 10a-c according to Equation 5. In this manner, the total power usage, P, is estimated based on the total current, I_{supply}, determined in step 30, and the voltage measured across one of the plurality of branch circuits 10a-c (as provided by the voltage sensor 16).

The skilled person shall appreciate that the total current, I_{supply}, determined in step 30 may take various forms, as described above. Hence, the estimate of the power usage, P, may similarly take different forms in dependence on the form of the total current, I_{supply}, determined in step 30. Accordingly, the following examples are not intended to be limiting on the scope of the invention.

In an example, the total current, I_{supply}, determined in step 30 is assumed to be constant between load change events and is determined in the manner described above. In which case, the total power usage of the plurality of branch circuits 10a-c may be determined according to Equation 5, where the total current, I_{supply}, is a time-varying, step-wise, signal determined in step 30 and V1 is a corresponding is a time-varying, step-wise, signal formed by the series of voltages corresponding to the measured voltage after each load change event detected in step 26. In this manner, the voltage V1 and the total current, I_{supply}, may be multiplied together to determine the total power usage. Alternatively, the voltage V1 and the total current, I_{supply}, at the end of each load change event may be multiplied together to determine the total power usage between load change events.

It is noted that the steps of the method 20 are merely provided as an example of the invention and it shall be appreciated that steps may be altered, added and removed as will be appreciated by the person skilled in the art.

For example, the method 20, described above, includes steps for determining and refining the estimation of the line impedance, RL, where an accurate estimation of the line impedance has not been determined previously. However, it shall be appreciated that, in other examples, the total power usage of the plurality of branch circuits 10a-c may be determined in accordance with steps 30 and 32 of the method 20 once an estimation of the line impedance has been determined.

Many modifications may be made to the above-described examples without departing from the scope of the appended claims.

1. A method of estimating power usage in an electricity distribution apparatus for a plurality of electrical loads, the electricity distribution apparatus comprising an electrical circuit including a plurality of branch circuits arranged in parallel, each branch circuit being coupled to one or more of the plurality of electrical loads, the electrical distribution apparatus being configured to distribute electrical power, received via a supply line from a supply of electrical power, across the electrical circuit, the method comprising:
measuring voltage across at least one of the plurality of branch circuits;
measuring current in a monitored branch circuit of the plurality of branch circuits; and
detecting a first type of load change event if there is a change in the measured current and a corresponding change in the measured voltage, wherein the change in the measured current and the corresponding change in the measured voltage correspond to a change of load on the electrical circuit provided by the one or more electrical loads in the monitored branch circuit;
estimating line impedance in the supply line in dependence on detecting a load change event of the first type, wherein the estimation of the line impedance is based on the change in the measured current and the change in the measured voltage corresponding to the detected load change event of the first type; and
estimating a total power usage of the electrical circuit based on: a voltage of the supply of electrical power; the measured voltage; and the estimation of the line impedance.

2. The method according to claim 1, wherein, for the first type of load change event, the change in the measured current exceeds a threshold change of current.

3. The method according to claim 2, wherein the threshold change of current is configured to exceed:
any change in the measured current originating in the supply of electrical power; and
any change in the measured current corresponding to a change of load on the electrical circuit provided by one or more of the electrical loads in any of the plurality of branch circuits other than the monitored branch circuit.

4. The method according to claim 1, wherein the estimation of the line impedance, RL, is determined according to the equation:
$$RL = \frac{- {ΔV}_{1}}{Δ {I}_{1}}$$
where RL is the estimated line impedance; ΔV₁ is the change in the measured voltage corresponding to the detected load change event of the first type; and ΔI₁ is the change in the measured current corresponding to the detected load change event of the first type.

5. The method according to claim 1, comprising:
re-estimating the line impedance if:
an additional load change event of the first type is detected; and
the measured voltage associated with the additional load change event of the first type is greater than the measured voltage associated with the load change event upon which the current estimate of the line impedance is based;
wherein the re-estimation of the line impedance is based on the change in the measured current and the change in the measured voltage corresponding to the additional load change event of the first type.

6. The method according to claim 1, comprising: detecting a second type of load change event if there is a change in the measured voltage that corresponds to a change of load on the electrical circuit provided by one or more of the plurality of electrical loads.

7. The method according to claim 6, wherein, for each of the first and second types of load change events, the change in the measured voltage exceeds a threshold change of voltage.

8. The method according to claim 7, wherein the threshold change of voltage is configured to exceed any changes in the measured voltage originating in the supply of electrical power.

9. The method according to claim 1, comprising: estimating a total current in the electrical circuit, I_{supply}, according to the equation:
$${I}_{supply} = \frac{{V}_{supply} - {V}_{1}}{RL}$$
where I_{supply} is the total current in the electrical circuit; V_{supply} is the voltage of the supply of electrical power; V1 is the measured voltage; and RL is the estimation of the line impedance; and using the estimated total current, I_{supply}, to estimate the total amount of power usage in the electrical circuit.

10. The method according to claim 9, wherein the total current in the electrical circuit, I_{supply}, is estimated in response to detecting a load change event of the first or second type.

11. The method according to claim 6, comprising:
detecting a series of load change events, of the first and/or second type, over a period of time based on respective changes in the measured voltage; and
estimating the total current in the electrical circuit, I_{supply}, in a step-wise manner that varies with time, wherein successive step changes in the total current in the electrical circuit, ΔIsupply, correspond to successive load change events in the series of load change events and each of the successive step changes in the total current in the electrical circuit, ΔIsupply, are estimated according to the equation:
$$Δ Isupply = \frac{- ΔV1}{RL}$$
where ΔIsupply is the step-change in the total current in the electrical circuit corresponding to one of the series of load change events; ΔV1 is the change in the measured voltage corresponding to that load change event; and RL is the estimation of the line impedance; and
using the estimated total current, I_{supply}, to estimate the total amount of power usage in the electrical circuit.

12. The method according to claim 9, wherein the estimate of the total power usage of the electrical circuit is based on the estimate of the total current and the measured voltage.

13. A non-transitory, computer-readable storage medium storing instructions thereon that when executed by a processor causes the processor to perform the method according to claim 1.

14. A control system of an electricity distribution apparatus for a plurality of electrical loads, the electricity distribution apparatus comprising an electrical circuit including: a plurality of branch circuits arranged in parallel, a current sensor arranged for measuring the current in a monitored branch circuit of the plurality of branch circuits, and a voltage sensor arranged for measuring the voltage across one of the plurality of branch circuits, wherein, in use, each branch circuit is coupled to one or more of the plurality of electrical loads and the electrical distribution apparatus is configured to distribute electrical power, received via a supply line from a supply of electrical power, across the electrical circuit, and wherein, in use, the control system is configured to estimate a total power usage of the electrical circuit according to the method of claim 1.
